(19) United States
(12) Patent Application Publication
(10) Pub. No.: US 2021/0333385 A1
(43) Pub. Date: Oct. 28, 2021

(54) ENHANCED RANGE-VELOCITY FINDING IN FREQUENCY-MODULATED CONTINUOUS WAVE RADAR

(71) Applicant: SEMICONDUCTOR COMPONENTS INDUSTRIES, LLC, Phoenix, AZ (US)

(72) Inventors: Nader ROHANI, Scottsdale, AZ (US); Youssef ATRIS, Gilbert, AZ (US)

(73) Assignee: SEMICONDUCTOR COMPONENTS INDUSTRIES, LLC, Phoenix, AZ (US)

(21) Appl. No.: 16/857,102

(22) Filed: Apr. 23, 2020

(51) Int. Cl. G01S 13/58; G01S 13/931; G01S 7/35

(52) U.S. Cl. CPC G01S 13/584; G01S 13/931; H03M 7/40; G01S 2007/356; G01S 7/352

(57) ABSTRACT

A radar detection method that comprises receiving a signal from each of one or more receive antennas, each received signal including a plurality of chirps, each received signal corresponding to a transmit signal reflected by a reflector; obtaining a range signal by downmixing each received signal with a reference chirp signal; performing a frequency transform on the range signal to obtain, for each chirp in the plurality of chirps, a set of range coefficients; compressing each set of range coefficients to obtain a plurality of compressed coefficient sets, wherein each compressed coefficient set corresponds to a set of range coefficients; storing each compressed coefficient set in a buffer; decompressing each compressed coefficient set to obtain buffered sets of range coefficients; processing the buffered sets of range coefficients to determine a range to a reflector of the transmit signal; and reporting the range to an electronic control unit.

### FIELD

This application relates generally to frequency-modulated continuous wave (FMCW) radar systems, and more particularly to systems that employ data compression for range-velocity fast Fourier transform (FFT) engines using Huffman Block floating point data.

### BACKGROUND

In the quest for ever-safer and more convenient transportation options, many car manufacturers are developing self-driving cars which require an impressive number and variety of sensors, often including arrays of acoustic and/or electromagnetic sensors to monitor the distance between the car and any nearby persons, pets, vehicles, or obstacles. Attempts to provide systems which alternate between provision of range determination and velocity determination for on one or more targets (e.g., vehicles) have not been wholly satisfactory. Thus, there is room for improvement in the art.

### SUMMARY

An example of this disclosure is a radar detection method that comprises receiving a signal from each of one or more receive antennas, each received signal including a plurality of chirps, each received signal corresponding to a transmit signal reflected by a reflector; obtaining a range signal by downmixing each received signal with a reference chirp signal; performing a frequency transform on the range signal to obtain, for each chirp in the plurality of chirps, a set of range coefficients; compressing each set of range coefficients to obtain a plurality of compressed coefficient sets, wherein each compressed coefficient set corresponds to a set of range coefficients; storing each compressed coefficient set in a buffer; decompressing each compressed coefficient set to obtain buffered sets of range coefficients; processing the buffered sets of range coefficients to determine a range to a reflector of the transmit signal; and reporting the range to an electronic control unit.

Another example of this disclosure is a radar transceiver that comprises one or more transmitter circuits configured to drive a transmit antenna to emit a first transmit signal, the first transmit signal comprising a plurality of chirps; a receiver configured to detect a second signal using a receive antenna during a detection period; and a processor coupled to the one or more transmitter circuits and the receiver, and configured to: downmix the second signal with a reference chirp signal to obtain a range signal; perform a frequency transform on the range signal to obtain, for each chirp in the plurality of chirps, a set of range coefficients; compress each set of range coefficients to obtain a compressed coefficient set; store each compressed coefficient set in a buffer; decompress each compressed coefficient set to obtain buffered sets of range coefficients; and process the buffered sets of range coefficients to determine a range to a reflector of the first transmit signal.

Another example of this disclosure is a method of generating a velocity matrix, comprising: receiving a range signal using processor; producing a set of range coefficients by performing a first fast Fourier transform on the range signal, the set of range coefficients corresponding to a first matrix; encoding the set of range coefficients of the first matrix in accordance with a Huffman encoding algorithm; producing a second matrix by transposing the first matrix, the second matrix having a set of elements; decoding the set of elements of the second matrix in accordance with the Huffman encoding algorithm; and generating a velocity matrix by performing a second fast Fourier transform on the set of elements.

Another example of this disclosure is a radar system, comprising: a memory configured to receive a plurality of range signals; a first processor coupled to the memory, wherein the first processor is configured to determine a plurality of range coefficients by performing a first frequency transform on the plurality of range signals; a first codec coupled to the first processor, wherein the first codec is configured to compress the plurality of range signals as a first set of elements using a Huffman encoding algorithm; a second processor configured to generate a second set of elements by performing a transpose operation on the first set of elements; a second codec configured to decompress the second set of elements; and a third processor configured to determine a velocity matrix by performing a second frequency transform on the second set of elements.

### BRIEF DESCRIPTION OF THE DRAWINGS

FIG. 1 is an overhead view of a vehicle equipped with sensors, in accordance with an example of this disclosure;

FIG. 2 is a block diagram of a driver-assistance system, in accordance with an example of this disclosure;

FIG. 3 is a schematic diagram of a reconfigurable multiple input multiple output radar system, in accordance with an example of this disclosure;

FIG. 4 is a block diagram of a radar system, in accordance with an example of this disclosure;

FIGS. 5A-5E illustrate a chirp signal-based radar detection method, in accordance with an example of this disclosure;

FIG. 6 illustrates a radar processor, in accordance with an example of this disclosure;

FIG. 7 illustrates a radar detection method, in accordance with an example of this disclosure;

FIG. 8 illustrates a method of generating a velocity matrix in a radar system, in accordance with an example of this disclosure; and

FIG. 9 illustrates aspects of a radar system, in accordance with an example of this disclosure.

### DETAILED DESCRIPTION

The accompanying drawings and following detailed description do not limit the disclosure, but on the contrary, they provide the foundation for understanding all modifications, equivalents, and alternatives falling within the scope of the appended claims. Specific configurations, parameter values, and operation examples are provided for the purposes of explanation rather than for circumscribing any scope of disclosure.

In one or more examples of this disclosure, the size of a transpose buffer between a range FFT engine and a velocity FFT engine is minimized through Huffman encoding of block floating point data corresponding to the output of the range FFT engine, without causing any meaningful reduction in resolution.

In one or more examples of this disclosure, minimization of the transpose buffer (930, 950) between the range FFT engine and the velocity FFT engine is enables data to be processed more quickly than would otherwise be the case.

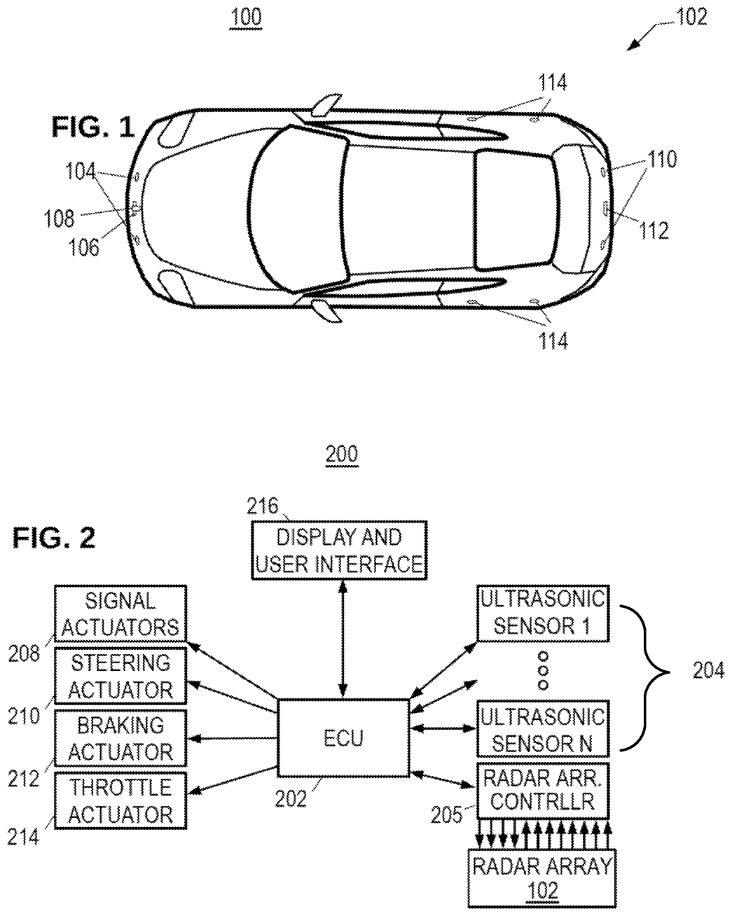

FIG. 1 illustrates a vehicle 100, in accordance with an example of this disclosure. Vehicle 100 is equipped with an array 102 of radar antennas, including antennas 104 for short range sensing (e.g., for park assist), antennas 106 for mid-range sensing (e.g., for monitoring stop & go traffic and cut-in events), antennas 108 for long range sensing (e.g., for adaptive cruise control and collision warning), each of which may be placed behind the front bumper cover. Antennas 110 for short range sensing (e.g., for back-up assist) and antennas 112 for mid-range sensing (e.g., for rear collision warning) may be placed behind the back-bumper cover. Antennas 114 for short range sensing (e.g., for blind spot monitoring and side obstacle detection) may be placed behind the car fenders. Each antenna and each set of antennas may be grouped in one or more arrays. Each array may be controlled by a radar array controller (e.g., 205). Each set of antennas may perform multiple-input multiple-output (MIMO) radar sensing. The type, number, and configuration of sensors in the sensor arrangement for vehicles having driver-assist and self-driving features varies. The vehicle 100 may employ the sensor arrangement for detecting and measuring distances/directions to objects in the various detection zones to enable the vehicle 100 to navigate while avoiding other vehicles and obstacles.

FIG. 2 is a block diagram of a driver-assistance system 200 for a vehicle 100, in accordance with an example of this disclosure. FIG. 2 shows an electronic control unit (ECU) 202 coupled to the various ultrasonic sensors 204 and a radar array controller 205 as the center of a star topology. The ECU 202 may be an embedded system that controls one or more of the electrical systems or subsystems in the vehicle 100. Other topologies including serial, parallel, and hierarchical (tree) topologies, are also suitable and contemplated for use in accordance with the principles disclosed herein. The radar array controller 205 couples to the transmit and receive antennas in the radar antenna array 102 to transmit electromagnetic waves, receive reflections, and determine a spatial relationship of the vehicle 100 to its surroundings. The radar array controller 205 couples to carrier signal generators (404). In at least one example, the radar array controller 205 controls the timing and order of actuation of a plurality of carrier signal generators (404).

To provide automated parking assistance, the ECU 202 may further connect to a set of actuators such as a turn-signal actuator 208, a steering actuator 210, a braking actuator 212, and throttle actuator 214. ECU 202 may further couple to a user-interactive interface 216 to accept user input and provide a display of the various measurements and system status.

Using the interface, sensors, and actuators, ECU 202 may provide automated parking, assisted parking, lane-change assistance, obstacle and blind-spot detection, autonomous driving, and other desirable features. In an automobile, the various sensor measurements are acquired by one or more ECU 202, and may be used by the ECU 202 to determine the automobile's status. The ECU 202 may further act on the status and incoming information to actuate various signaling and control transducers to adjust and maintain the automobile's operation. Among the operations that may be provided by the ECU 202 are various driver-assist features including automatic parking, lane following, automatic braking, and self-driving.

To gather the necessary measurements, the ECU 202 may employ a MIMO radar system (e.g., 300). Radar systems operate by emitting electromagnetic waves which travel outward from the transmit antenna before being reflected towards a receive antenna. The reflector can be any moderately reflective object in the path of the emitted electromagnetic waves. In accordance with one or more examples of this disclosure, a reflector is an object which reflects a transmit signal, such as a person or vehicle. A reflector can also be called a target. By measuring the travel time of the electromagnetic waves from the transmit antenna to the reflector and back to the receive antenna, the radar system can determine the distance to the reflector and its velocity relative to the vehicle 100. If multiple transmit or receive antennas are used, or if multiple measurements are made at different positions, the radar system can determine the direction to the reflector and hence track the location of the reflector relative to the vehicle 100. With more sophisticated processing, multiple reflectors can be tracked. At least some radar systems employ array processing to “scan” a directional beam of electromagnetic waves and construct an image of the vehicle's surroundings. Both pulsed and continuous-wave implementations of radar systems can be implemented.

In accordance with one or more examples of this disclosure, a transmit signal is a radio signal emitted by one or more antennas. For example, FIG. 3 illustrates a radar system 300 having a MIMO configuration, in which J transmitters are collectively coupled to M transmit antennas 301 to send transmit signals 307. The M possible signals 307 may variously reflect from one or more targets to be received as receive signals 309 via N receive antennas 302 coupled to P receivers. Each receiver may extract the amplitude and phase, or travel delay associated with each of the M transmit signals 307, thereby enabling the system to obtain N*M measurements (though only J*P of the measurements may be obtained concurrently). The processing requirements associated with each receiver extracting J measurements can be reduced via the use of time division multiplexing and/or orthogonal coding. The available antennas are systematically multiplexed to the available transmitters and receivers to collect the full set of measurements for radar imaging.

In accordance with one or more examples of this disclosure, FMCW radar is used for measuring—relative a vehicle (e.g., 100) carrying a radar system 300—target position, velocity, azimuth angle, and elevational angle. The radar system 300 includes a plurality of receiver antennas (e.g., more than four). The radar system 300 transmits the transmit signal 307. The transmitted signal 307 and the target echo signal 309 are heterodyned using a mixer (407). The output signal from the mixer (407) is converted to a digital signal by an analog-to-digital converter (417). The digital signal is then processed by a processor (419).

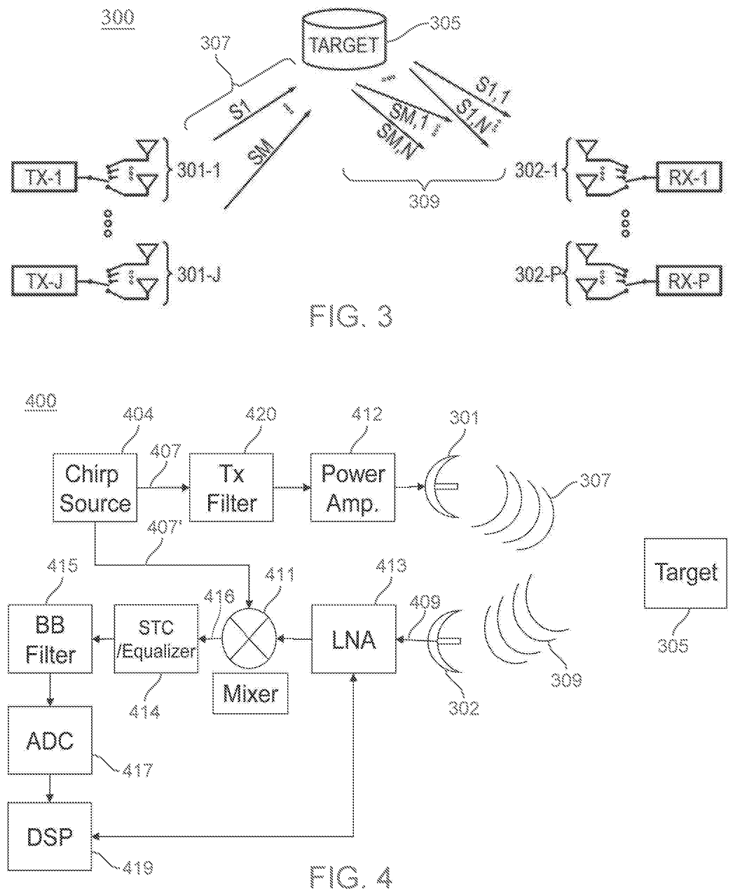

FIG. 4 illustrates a radar system 400 (e.g., 300) in block diagram form, in accordance with an example of this disclosure. In at least one example, the radar system 400 is implemented as an integrated circuit in a packaged chip, such as a front-end chip. Radar system 400 includes a carrier signal generator 404, a transmission filter 420, an amplifier 412, and transmit antennas 301 which can transmit signals 307 (e.g., chirp signals) based on the output of the carrier signal generator 404. Radar system 400 also includes receive antennas 302, a low noise amplifier 413, and a mixer 411. Downmixing is a method of generating an intermediate frequency signal by heterodyning a carrier signal with a local oscillator signal, such as when mixer 411 mixes signals (e.g., 409) detected by receive antennas 302 with the signal from the carrier signal generator 404. Carrier signal generator 404 may comprise a local oscillator, which is an electronic oscillator that generates such local oscillator signal.

Low noise amplifier 413 is used to amplify signals 409 detected using receive antennas 302. Radar system 400 also includes a sensitivity time controller and equalizer 414, a broadband filter 415, an analog-to-digital converter 417 and a processor 419. The processor 419 and low noise amplifier 413 can be coupled for bi-directional communication (not shown).

In examples of this disclosure, carrier signal generator 404 is coupled to the radar array controller 205. Carrier signal generator 404 includes a chirp generator to create a FMCW signal. In one or more examples of this disclosure, a chirp is a frequency-modulated radio signal whose frequency increases or decreases linearly over a time period. The chirp rate of the carrier signal generator 404 may be controlled by the radar array controller 205. In at least one example, the carrier signal generator 404 can be deactivated by the radar array controller 205 to provide an unmodulated carrier signal. The carrier signal generator 404 may be implemented as a local oscillation (LO) signal generator as a fractional-N phase lock loop (PLL) with a ΣΔ controller, or as a direct-digital synthesis (DDS) generator.

Carrier signal generator 404 is connected to transmit antennas 301 through transmission filter 410 and amplifier 412. Carrier signal generator 404 is connected to receive antennas 302 through mixer 411 and low noise amplifier 413. Carrier signal generator 404 generates a signal 407 (e.g., a chirp signal). Amplifier 412 receives the signal 407 from carrier signal generator 404. Signal 407 is received by transmit antennas 301, and signal 307 is transmitted by transmit antennas 301 as a result. Amplifier 412 drives transmit antennas 301 to emit signal 307, based on (lower amplitude) signal 407.

During operation, the signals (e.g., 309) that are reflected by different objects (targets) 305 are received by the radar system 400 and mixed with the transmitted signal (407′) to generate an intermediate frequency (IF) signal whose frequency depends on the target range and relative velocity. An IF is a frequency to which a carrier wave is shifted as an intermediate step in transmission or reception. The IF signal is sampled by an analog-to-digital converter (ADC) (e.g., 417) at a sampling frequency fₛ and processed by a processor (e.g., ECU 202, DSP 419).

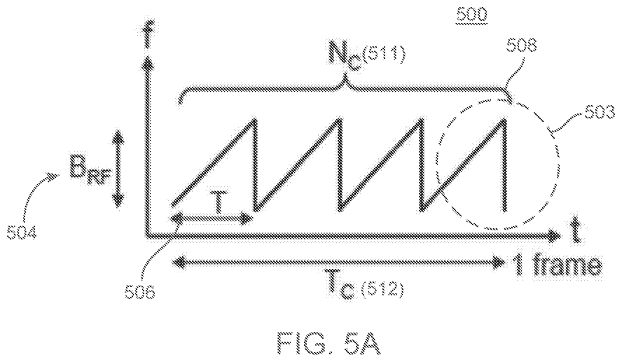

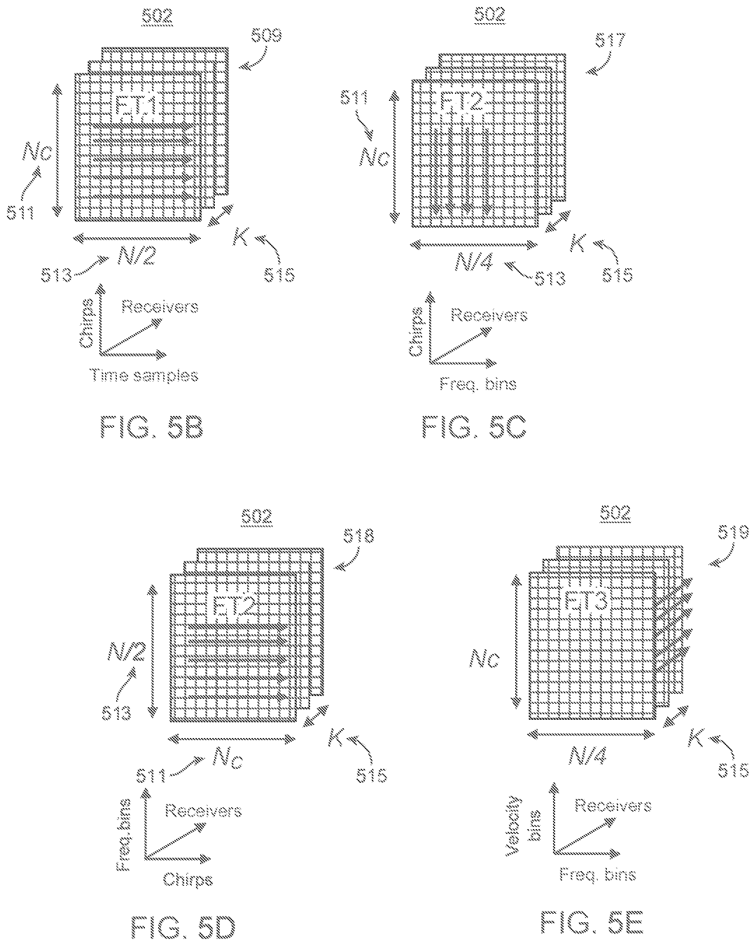

FIG. 5A illustrates a chirp signal profile 500, in accordance with an example of this disclosure. FMCW radar (e.g., 400) transmits chirp signals (e.g., 307) in order to detect a target's 305 range and relative velocity. As noted, a chirp 503 is a frequency-modulated radio signal whose frequency increases or decreases linearly over a time period. A chirp signal is a frequency-modulated radio signal composed of a series of individual chirps (e.g., 503). A chirp 503 is characterized by, among other things, its carrier frequency, chirp bandwidth 504 and chirp duration 506. A chirp sequence 508 is a portion of a chirp signal and is defined by the number of chirps N_{C} 511 and by a chirp period T_{C} 512. FIG. 5A shows four chirps 503 of duration 506 T. Hence, the value of N_{C} in FIG. 5A is four (4). Understanding the concepts illustrated in FIG. 5A will make the disclosure of FIGS. 5B-5E easier to assimilate.

FIGS. 5B-5E illustrate a radar detection method 502 which is based on chirps 503, in accordance with an example of this disclosure.

FIG. 5B illustrates a detection matrix 509 formed according to method 502. As illustrated in FIG. 5B, the method 502 comprises forming the three-dimensional detection matrix 509 (using e.g., processor 419) from signals 309, 409 detected by an arrangement of receive antennas 302 in response to chirps 503 transmitted by an arrangement of transmit antennas 301. The detection matrix 509 has multiple rows (N_{C}) 511. Each row 511 corresponds to one chirp 503. The detection matrix 509 formed by the processor 419 has multiple columns 513, each of which corresponds to a respective sample within each chirp signal 309. The detection matrix 509 formed by the processor 419 has multiple (K) planes 515, each of which corresponds to a receive antenna (e.g., 302) which detected a given (reflected) chirp signal 309. In one or more examples of this disclosure, the information of the detection matrix 509 is buffered using a buffer memory (e.g., 616).

FIG. 5C illustrates a range matrix 517 formed according to the method 502. The range matrix 517 is generated by performing a frequency transform (FT1) (e.g., FFT) on a portion of each row 511 of the detection matrix 509. Optionally, one or more targets 305 with high signal amplitude are identified at this stage. According to the method 502, a velocity matrix (519) will be derived from the range matrix 517.

Mathematically, this derivation is achieved by performing a frequency transform (FT2) on a portion of each column 513 (or only those columns having signal energy from the identified targets) of the range matrix 517. (Optionally, one or more targets 305 with high signal amplitude are identified at this stage.) However, in practice the memory addresses of information of the range matrix 517 must often be rearranged so that a processor (e.g., 419) can perform the second frequency transform (e.g., when the dimensions of the matrix in question are not the same).

This concept is illustrated in FIG. 5D, in which each plane 515 for each receiver antenna 302 of matrix 517 has been transposed to form matrix 518. Performing FT2 on each column of matrix 517 is mathematically equivalent to performing FT2 on each row of matrix 518. Encoding and compressing the data of matrix 517 streamlines the transpose operations, which enables the velocity matrix 519 of FIG. 5E to be generated more quickly.

FIG. 5E illustrates a third frequency transform (FT3) being performed on values in the velocity matrix 519, such as to produce an azimuth angle matrix (not show). In accordance one of more examples of this disclosure a frequency transform can thereafter be performed on the values of the azimuth angle matrix. In order to perform each such frequency transform operation, one or more matrixes will be transposed using a transpose buffer (930, 950) or other memory (e.g., the information of some matrix cells will be moved in memory or the addresses of some matrix cells will be rewritten).

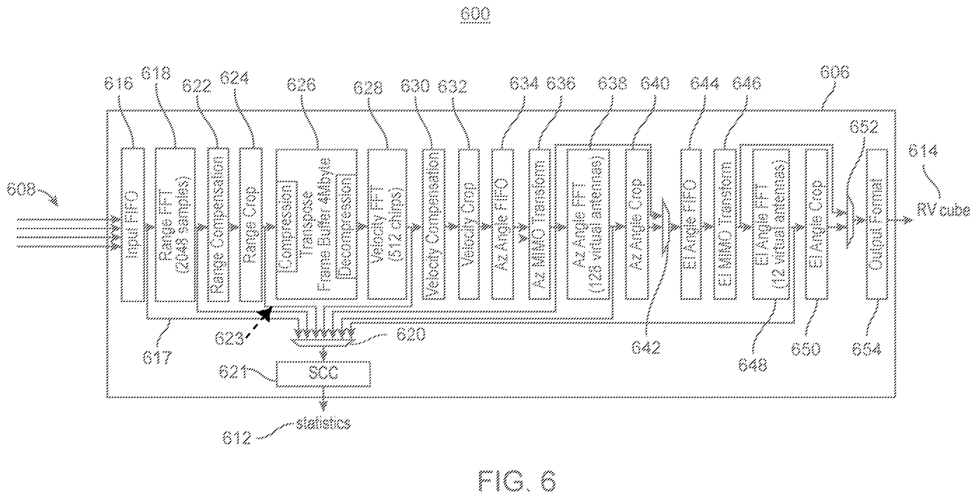

FIG. 6 illustrates a radar processor 600, in accordance with an example of this disclosure. In at least one example of this disclosure, radar processor 600 is a circuit for controlling and analyzing aspects of FMCW radar for an automobile (e.g., 100). Radar processor 600 comprises multiple components, with each component having one or more functions. In some examples of this disclosure, some of the functions may be performed by fewer components, with some components being subsumed within others. In the example illustrated in FIG. 6, components of the radar processor 600 reside on an integrated circuit 606. One such component is FIFO memory circuit 616. FIFO memory circuit 616 merges data 608 from parallel input streams from the receiver antennas 302 into a single output stream 617. As FIFO memory circuit 616 has a FIFO architecture, the first chirp data from the first channel is output (as output stream 617) first, followed by the first chirp data of second channel, followed by first chirp of third channel and so on. Output Stream 617 is output to range transform circuit (range FFT engine) 618 and radar multiplexor 620. Radar multiplexor 620 multiplexes the output 617 from FIFO memory circuit 616 with output from other components. The multiplexed data is used by statistical compilation circuit (SCC) 621 to generate statistical data 612. In at least one example of this disclosure, statistical data 612 is transmitted to ECU 202. The FIFO output stream 617 is processed by range transform circuit 618 to determine the position of a reflector (e.g., target 305). The amount of data processed by transform circuit 618 corresponds to the quantity of samples per chirp multiplied by the quantity of chirps in each channel multiplied by the quantity of channels (e.g., the quantity of receive antennas 302). Range transform circuit 618 applies a first fast Fourier transform (FFT) to the samples of each chirp in stream 617, as discussed in relation to FIG. 5B. In some examples of this disclosure, a compensation circuit 622 performs one or more compensation operations on at least some of the transformed chirp sample data. In some examples of this disclosure, a quantization circuit 624 may crop or truncate at least some of the transformed chirp data. Quantization and quantizing can include (a process of) mapping input values from a large set to output values in a smaller set. All such range FFT results 623 are output to multiplexor 620 and to transpose buffer unit (TBU) 626. TBU 626 compresses the FFT results 623. In one or more examples of this disclosure, TBU 626 comprises one or more transpose buffers (930, 950). In one or more examples of this disclosure, TBU 626 is connected to one or more transpose buffers (930, 950). The TBU 626 transposes (matrixes of) the compressed range FFT results for estimating target velocity (see FIG. 5C). In one or more examples of this disclosure, the TBU 626 stores portions of the compressed range FFT results 623 in a transpose buffer (930, 950) during transpose operations. The TBU 626 decompresses the transposed range FFT results using a decoder (970). In some examples of this disclosure, TBU 626 comprises one or more decoders (970). In some examples of this disclosure, TBU 626 is connected to one or more decoders (970). The decompressed data is output by TBU 626 to velocity transform circuit (velocity FFT engine) 628, which performs a second FFT (FT2) on the decompressed data to estimate the velocity of the target.

As noted, TBU 626 compresses the range FFT results 623. As part of the data compression process, the TBU 626 encodes the range FFT 623 results using a Huffman encoding method, in which more frequently occurring symbols—such as binary symbols—are encoded with fewer bits than are symbols which occur less frequently in a set. In at least one example of this disclosure, the TBU 626 encodes the range FFT results 623 by applying a Huffman block floating point encoding algorithm. In one or more examples of this disclosure, TBU 626 includes one or more encoders (960). In one or more examples of this disclosure, TBU 626 is coupled to one or more encoders (960). In one or more examples of this disclosure, TBU 626 includes one or more decoders (970). In one or more examples of this disclosure, TBU 626 is coupled to one or more decoders (970). In one or more examples of this disclosure, TBU 626 includes one or more codecs (921). In at least one example of this disclosure, TBU 626 is coupled to one or more codecs (921).

The output of the transform circuit 618 is complex. The real part and the imaginary part of each complex number are normalized and scaled by a constant factor of 1.414 by the compensation circuit 622. Normalization can include mapping a set of data to a new scale and can include scaling a variable quantity to have values from zero (0) to one (1). The normalized and scaled data from the compensation circuit 622 is processed by the quantization circuit 624 in at least twelve separate levels, (input of quantization circuit=range FFT/Max (range FFT)/1.414).

The output of compensation circuit is 622 is represented—by the quantization circuit 624—as a fixed 20-bit block floating point number. The 20-bit block floating point number includes one sign bit, a 4-bit common exponent, and a 15-bit fractional part (mantissa), (e.g., 1-bit sign+4-bit common exponent+15-bit fractional). A technical advantage of the 15-bit length of the fractional portion of the 20-bit block floating point number is that the 15-bit length minimizes loss of data resolution. In at least one example of this disclosure, those blocks of data having different mantissas may share a 4-bit common exponent.

The output 623 from the quantization circuit 624 is thus a plurality of floating-point numbers. In at least one example of this disclosure, the output 623 from the quantization circuit 624 comprises block floating point numbers. These block floating point numbers (of each chirp from multiple (K) channels) are encoded by the TBU 626 using a Huffman coding algorithm, in which more frequently occurring values (in the data being encoded) are represented with shorter codes, and less frequently occurring values are represented by longer codes within a Huffman dictionary generated by the TBU 626 as part of the encoding process. TBU 626 stores the encoded range (compressed) data and the Huffman dictionary in a transpose buffer (930, 950). The encoded range data is transposed, and then decompressed in accordance with the Huffman dictionary. This decompressed range data is then output to the velocity transform circuit 628.

A technical benefit of having the compensation circuit 622 and the quantization circuit 624 perform in the manner described is that the size of the transpose buffer (930, 950) necessary to enable the TBU 626 to transpose the range data (so that the range data can be translated into velocity information) is significantly smaller (in many cases approximately 90% smaller) than would otherwise be the case, with minimal loss of resolution. In some examples, the error rate of the quantization circuit's 624 floating point encoding is less than 1/(2*N), where N is the bit resolution of the chirp 503 samples. In some examples, the data loss rate associated with data compression-decompression by the TBU 626 is also 1/(2*N). Thus, the radar processor 600 enables target 305 velocities to be calculated more quickly and efficiently than would otherwise be possible—without any meaningful diminution in accuracy.

Velocity transform circuit 628 performs a second FFT (FT2) on the decompressed data from the TBU 626. The output (e.g., velocity data) from the velocity transform circuit 628 is processed in a manner which is not unlike that of the output from range transform circuit 618. The output from velocity transform circuit 628 (being a velocity matrix) is normalized and standardized by velocity compensation circuit 630 and truncated by velocity cropping circuit 632. Such standardizing can include transforming data (e.g., velocity data) to have a mean of zero (0) and a standard deviation of one (1).

The velocity data is then output to azimuth angle FIFO memory 634. Azimuth angle FIFO memory 634 buffers the (normalized and standardized) velocity data for the azimuth angle transpose circuit 636. Azimuth angle transpose circuit 636 transposes the (Fourier) transformed velocity data as received from azimuth angle FIFO memory 634. Azimuth angle transform circuit 638 performs a third FFT on the (transformed) velocity data (thereby generating azimuth angle data). The azimuth angle data generated by the angle transform circuit 638 is truncated by azimuth angle cropping circuit 640 and multiplexed with output from (azimuth) angle transpose circuit 636 by multiplexing circuit 642.

The output from multiplexing circuit 642 is received by elevational angle FIFO memory 644. Elevational angle FIFO memory 644 buffers the output from multiplexing circuit 642 for processing by elevational angle transform circuit 646. Elevational (angle) transform circuit 646 transposes the azimuth angle (matrix) data, and the elevational transform circuit 648 performs a fourth FFT on the azimuth angle data, producing an elevational angle matrix (not shown). The elevational angle data is cropped by elevation angle cropping circuit 650. The output from the elevational transform circuit 646 is multiplexed with the output from elevational angle cropping circuit 650 by secondary multiplexing circuit 652. Output from secondary multiplexing circuit 652 is formatted by formatting circuit 654 and then output to other components such as ECU 202. The output from formatting circuit 654 can be in the form of a range-velocity cube 614. The range-velocity cube can be a data cube in which each dimension corresponds to one or more signals detected by a specific antenna and the cells represent rates of positional change of a target (reflector 305).

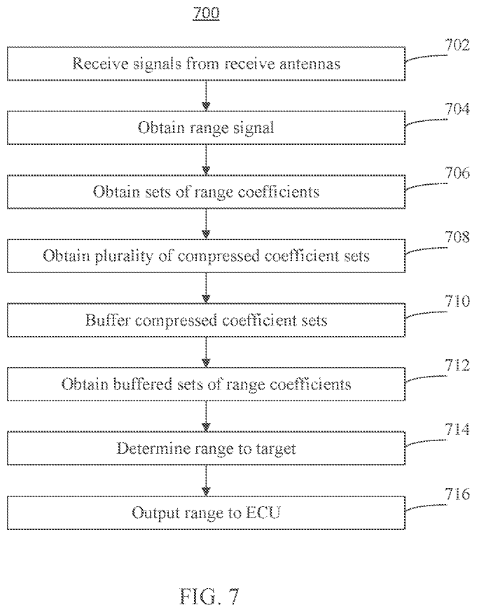

FIG. 7 illustrates a radar detection method 700, in accordance with an example of this disclosure. The method 700 involves receiving 702 a signal (e.g., 309, 409) from each of one or more receive antennas 302. Each received signal (e.g., 309, 409) includes a plurality of chirps 503, and each received signal (e.g., 309, 409) corresponds to a transmit signal (e.g., 307, 407) reflected by a reflector (e.g., target 305). The method 700 further involves obtaining 704 a range signal 416 by downmixing (see mixer 411, FIG. 4) each received signal (e.g., 309, 409) with a reference chirp signal 407′, where the range signal 416 is a signal which has been reflected by a reflector or target 305. In one or more examples of this disclosure, the reference chirp signal 407′ is a local oscillation signal from a local oscillator (e.g., 404) that is mixed with received signals to reduce the frequency of the received signals. The method 700 further involves obtaining 706 a set of range coefficients by performing a frequency transform (e.g., FT1) on the range signal 416 for each chirp 507 in the plurality (N_{C}) of chirps. In accordance with some examples of this disclosure, a range coefficient is a frequency coefficient of a range signal 416 which has been transformed using a frequency transform, such as the fast Fourier transform. The method 700 then involves obtaining 708 a plurality of compressed coefficient sets by compressing each set of range coefficients. In accordance with one or more examples of this disclosure, each compressed coefficient set corresponds to a set of range coefficients. The method 700 thereafter involves storing 710 each compressed coefficient set in a memory. In one or more examples of this disclosure, storing 710 each compressed coefficient set in a memory consists of storing each compressed coefficient set in a buffer memory (930, 950). Once the compressed coefficient sets have been buffered (stored) 710, the method 700 proceeds to the step of obtaining 712 (buffered) sets of range coefficients by decompressing each compressed coefficient. The next stage in the method 700 is determining 714 a range to a reflector 305 of the transmit signal 307. In some examples of this disclosure, determining 714 the range to the reflector 305 involves processing the buffered sets of range coefficients by one or more processors (e.g. 419). The method 700 then involves outputting (e.g., reporting) 716 the determined (714) distance between the vehicle 100 and the reflector 305 to the vehicle's ECU 202.

In one or more instances of method 700, compressing data (e.g., sets of range coefficients) and decompressing data each involve using a Huffman encoding dictionary, which maps symbols to their corresponding Huffman code. In at least one instance of method 700, compressing data also includes generating a Huffman encoding dictionary for each set of range coefficients based on a symbol probability within the set of range coefficients. Symbol probability can correspond to the number of occurrences of a symbol within a data set comprising a plurality of symbols. (Symbol probability reflects the relative likelihood that a particular symbol will be decoded from amongst the set of all possible symbols in a set, such as the set of symbols in a given Huffman dictionary.) In some instances of method 700, the Huffman encoding dictionary is stored in the buffer (930, 950) with its corresponding set of range coefficients.

In one or more instances of method 700, before each of the range coefficients in the set of range coefficients is compressed, each of the range coefficients is separated into real and imaginary parts, and then normalized, quantized, and standardized in accordance with a block floating-point algorithm (see discussion of 618, 622, 624 of FIG. 6). The block floating-point algorithm may be a process or algorithm that uses block floating-point arithmetic in which a block of data is assigned a single (common) exponent, and in which the common exponent is determined by the data element in the block of data having the greatest magnitude. In at least one instance of method 700, each normalized, quantized, and standardized real and imaginary part is represented as a 20-bit floating point number. In some examples, the 20-bit floating point number includes a 1-bit sign value, a 4-bit exponential value and a 15-bit fractional value.

In one or more examples of this disclosure, processing the buffered sets of range coefficients in method 700 to determine the range to the reflector 305 of the transmit signal 307 includes forming a range matrix 517 having the buffered sets of range coefficients as rows, and performing frequency transforms on columns of the range matrix 517 to obtain sets of velocity coefficients. In at least one example in accord with method 700, processing the buffered sets of range coefficients also includes forming a velocity cube 519 having sets of velocity coefficients associated with different antennas 302 as (K) layers, and performing frequency transforms across layers of the velocity cube to obtain sets of azimuth coefficients. In some instances of the method 700, processing the buffered sets of range coefficients further includes identifying energy peaks within the velocity cube 519 representing reflectors 305 of the transmit signal 307, and reporting a range value, a velocity value, and an azimuth value for each energy peak so determined. In at least one example of this disclosure an energy peak is a local maximal value of an amplitude over a relevant range.

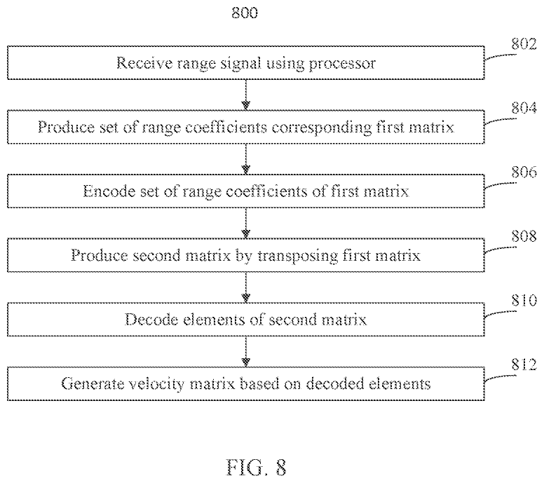

FIG. 8 illustrates a method 800 of generating a velocity matrix 519 in a radar system (e.g, 300, 400), in accordance with an example of this disclosure. The method 800 involves receiving 802 a range signal 416 (corresponding to a plurality (N_{C}, 511) of chirps 503) using processor 419 and producing 804 a set of range coefficients by performing a first fast Fourier transform (e.g., FT1) on the (digitized) range signal 416. In accordance with the method 800, the set of range coefficients corresponds to a first (range) matrix 517. The method 800 further includes encoding 806 the set of range coefficients of the first matrix 517 in accordance with a Huffman encoding algorithm, (which involves creating a Huffman dictionary for the encoded data). Thereafter, the method 800 involves producing 808 a second matrix 518 by transposing the first matrix 517. The second matrix 518 will, naturally, contain a set of elements (e.g., a plurality of matrix cells). The next step in method 800 is decoding 810 the set of elements of the second matrix 518 in accordance with the Huffman encoding algorithm by applying the Huffman dictionary to the set of elements of the second matrix 518. Thereafter, the method 800 involves generating 812 a velocity matrix 519 by performing a second fast Fourier transform (e.g., FT2) on the set of elements of matrix 518 (which is the transposed version of matrix 517).

In some instances of the method 800, transposing the first matrix 517 comprises storing elements of the first matrix 517 in a transpose buffer (930, 950). In accordance with one or more examples of this disclosure, encoding the set of range coefficients of the first matrix 517 in accordance with the Huffman encoding algorithm comprises generating a Huffman dictionary and storing the Huffman dictionary in the transpose buffer (930, 950). In at least one instance of method 800, decoding the set of elements of the second matrix 518 in accordance with the Huffman encoding algorithm comprises applying the Huffman dictionary to the set of elements of the second matrix 518.

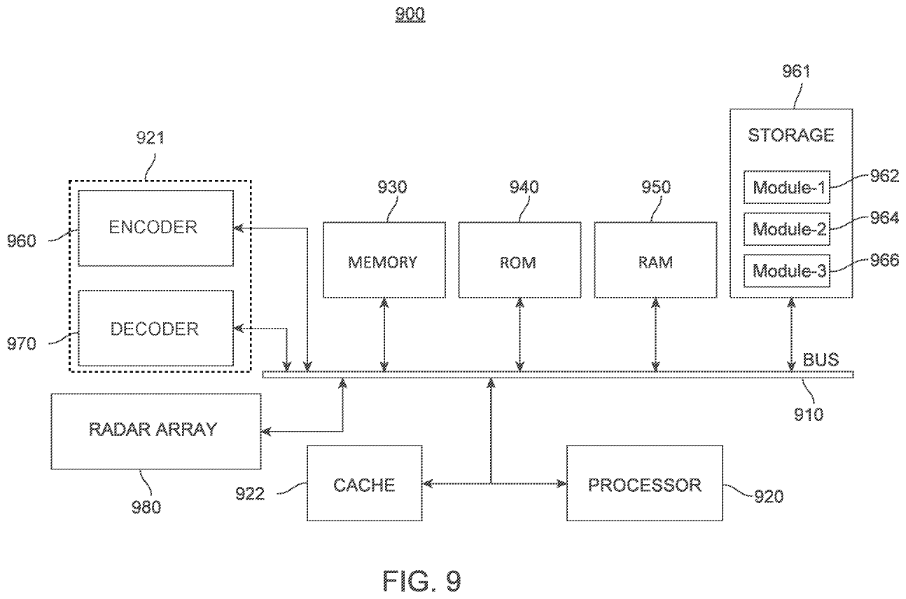

FIG. 9 illustrates a radar system 900 (e.g., 300, 400) which can be employed to practice the concepts and methods of this disclosure. As shown, system 900 can include a processing unit (CPU or processor) 920 (e.g., 419) and a system bus 910. System bus 910 interconnects various system components—such as system memory 930, read only memory (ROM) 940 and random-access memory (RAM) 950—to the processor 920. System 900 can further include one or more codecs 921 which can compress data and decompress data. System 900 can include one or more encoders 960 (which can compress data) and one or more decoders 970 (which can decompress compress data). In one or more examples of this disclosure, a codec 921 includes an encoder 960 and a decoder 970. System memory 930 and RAM 950 can include buffer memory. RAM 950 can be a memory buffer. RAM 950 can be a transpose buffer. The system bus 910 connects processor 920 and other components to a radar array 980 (e.g., 102) The processor 920 can comprise one or more digital signal processors. The system 900 can include a cache 922 of high-speed memory connected directly with processor 920, located near processor 920, or integral with the processor 920. The system 900 copies data from the memory 930 and/or storage 961 to the cache 922 for quicker access by the processor 920. The memory 930 can include multiple different types of memory with different performance characteristics. The processor 920 can include one or more sub-processors and a hardware module or software module, such as module-1 (962), module-2 (964), and module-3 (966) stored in storage 961. These and other modules can control or be configured to control the processor 920 to perform various actions. The system bus 910 may be any of several types of bus structures including a memory bus or memory controller, a peripheral bus, and a local bus using any of a variety of bus architectures. In at least one example, hardware that performs a function includes the software component stored in a non-transitory computer-readable medium coupled to the hardware—such as the processor 920, bus 910, encoder 960, decoder 970, codec 921 and so forth—necessary to carry out the function.

The various examples described above are provided by way of illustration and should not be construed to limit the scope of this disclosure. Various modifications and changes can be made in accord with the principles and examples described herein without departing from the scope of this disclosure or the claims which follow.

What is claimed is:

1. A radar detection method that comprises:
receiving a signal from each of one or more receive antennas, each received signal including a plurality of chirps, each received signal corresponding to a transmit signal reflected by a reflector;
obtaining a range signal by downmixing each received signal with a reference chirp signal;
performing a frequency transform on the range signal to obtain, for each chirp in the plurality of chirps, a set of range coefficients;
compressing each set of range coefficients to obtain a plurality of compressed coefficient sets, wherein each compressed coefficient set corresponds to a set of range coefficients;
storing each compressed coefficient set in a buffer;
decompressing each compressed coefficient set to obtain buffered sets of range coefficients;
processing the buffered sets of range coefficients to determine a range to a reflector of the transmit signal; and
reporting the range to an electronic control unit.

2. The radar detection method of claim 1, wherein said compressing and said decompressing each include using a Huffman encoding dictionary.

3. The radar detection method of claim 2, wherein said compressing includes generating a Huffman encoding dictionary for each set of range coefficients based on a symbol probability within the set of range coefficients.

4. The radar detection method of claim 3, wherein said Huffman encoding dictionary is stored in the buffer with a corresponding set of range coefficients.

5. The radar detection method of claim 1, wherein prior to said compressing, each range coefficient in the set of range coefficients is separated into real and imaginary parts, normalized, quantized, and standardized in accordance with a block floating-point algorithm.

6. The radar detection method of claim 5, wherein each normalized, quantized, and standardized real and imaginary part is represented as a 20-bit floating point number.

7. The radar detection method of claim 6, wherein the 20-bit floating point number includes a 1-bit sign value, a 4-bit exponential value and a 15-bit fractional value.

8. The radar detection method of claim 1, wherein processing the buffered sets of range coefficients to determine the range to the reflector of the transmit signal includes:
forming a range matrix having the buffered sets of range coefficients as rows;
performing frequency transforms on columns of the range matrix to obtain sets of velocity coefficients;
forming a velocity cube having sets of velocity coefficients associated with different antennas as layers;
performing frequency transforms across layers of the velocity cube to obtain sets of azimuth coefficients;
identifying energy peaks within the velocity cube representing reflectors of the transmit signal; and
reporting for each energy peak an associated range, velocity, and azimuth.

9. A radar transceiver, comprising:
one or more transmitter circuits configured to drive a transmit antenna to emit a first transmit signal, the first transmit signal comprising a plurality of chirps;
a receiver configured to detect a second signal using a receive antenna during a detection period; and
a processor coupled to the one or more transmitter circuits and the receiver, and configured to:
downmix the second signal with a reference chirp signal to obtain a range signal;
perform a frequency transform on the range signal to obtain, for each chirp in the plurality of chirps, a set of range coefficients;
compress each set of range coefficients to obtain a compressed coefficient set;
store each compressed coefficient set in a buffer;
decompress each compressed coefficient set to obtain buffered sets of range coefficients; and
process the buffered sets of range coefficients to determine a range to a reflector of the first transmit signal.

10. The radar transceiver of claim 9, wherein said compressing and said decompressing each include using a Huffman encoding dictionary.

11. The radar transceiver of claim 10, wherein said compressing includes generating a Huffman encoding dictionary for each set of range coefficients based on a symbol probability within the set of range coefficients.

12. The radar transceiver of claim 10, wherein said Huffman encoding dictionary is stored in the buffer with a corresponding set of range coefficients.

13. The radar transceiver of claim 9, wherein prior to said compressing, each range coefficient in the set of range coefficients is separated into real and imaginary parts, normalized, quantized, and standardized in accordance with a block floating-point algorithm.

14. The radar transceiver of claim 13, wherein each normalized, quantized, and standardized real part and imaginary part corresponds to a 20-bit floating point number corresponding to a 1-bit sign value, a 4-bit exponential value and a 15-bit fractional value.

15. The radar transceiver of claim 9, wherein processing the buffered sets of range coefficients to determine the range to the reflector of the first transmit signal includes:
forming a range matrix having the buffered sets of range coefficients as rows;
performing frequency transforms on columns of the range matrix to obtain sets of velocity coefficients;
forming a velocity cube, the velocity cube having sets of velocity coefficients associated with different antennas as layers;
performing frequency transforms across layers of the velocity cube to obtain sets of azimuth coefficients;
identifying a plurality of energy peaks within the velocity cube, wherein the plurality of energy peaks represents reflectors of the first transmit signal; and
reporting a range, velocity and azimuth corresponding to one or more energy peaks of the plurality of energy peaks.

16. A method of generating a velocity matrix in a radar system, comprising:
receiving a range signal using processor;
producing a set of range coefficients by performing a first fast Fourier transform on the range signal, the set of range coefficients corresponding to a first matrix;
encoding the set of range coefficients of the first matrix in accordance with a Huffman encoding algorithm;
producing a second matrix by transposing the first matrix, the second matrix having a set of elements;
decoding the set of elements of the second matrix in accordance with the Huffman encoding algorithm; and
generating a velocity matrix by performing a second fast Fourier transform on the set of elements.

17. The method of generating a velocity matrix in a radar system of claim 16, wherein transposing the first matrix comprises storing elements of the first matrix in a transpose buffer.

18. The method of generating a velocity matrix in a radar system of claim 17, wherein encoding the set of range coefficients of the first matrix in accordance with the Huffman encoding algorithm comprises generating a Huffman dictionary and storing the Huffman dictionary in the transpose buffer.

19. The method of generating a velocity matrix in a radar system of claim 18, wherein decoding the set of elements of the second matrix in accordance with the Huffman encoding algorithm comprises applying the Huffman dictionary to the set of elements of the second matrix.

20. A radar system, comprising:
a memory configured to receive a plurality of range signals;
a first processor coupled to the memory, wherein the first processor is configured to determine a plurality of range coefficients by performing a first frequency transform on the plurality of range signals;
a first codec coupled to the first processor, wherein the first codec is configured to compress the plurality of range signals as a first set of elements using a Huffman encoding algorithm;
a second processor configured to generate a second set of elements by performing a transpose operation on the first set of elements;
a second codec configured to decompress the second set of elements; and
a third processor configured to determine a velocity matrix by performing a second frequency transform on the second set of elements.

21. The radar system of claim 20, wherein the memory is a FIFO buffer memory, wherein the first codec and the second codec are different, and wherein the first processor, the second processor, and the third processor are different.
